(19) United States
(12) Patent Application Publication
(10) Pub. No.: US 2024/0176846 A1
(43) Pub. Date: May 30, 2024

(54) STOCHASTIC COMPUTING WITH GENERATED DETERMINISTIC SEQUENCES

(71) Applicant: INTERNATIONAL BUSINESS MACHINES CORPORATION, ARMONK, NY (US)

(72) Inventor: Bahman Hekmatshoartabari, White Plains, NY (US)

(21) Appl. No.: 18/071,895

(22) Filed: Nov. 30, 2022

(51) Int. Cl. G06F 17/17; G06F 7/02; G06F 7/60; H03K 19/20

(52) U.S. Cl. CPC G06F 17/17; G06F 7/02; G06F 7/607; H03K 19/20

(57) ABSTRACT

Providing neural network output values by receiving a neural network having defined node weights, determining network activations according to network input data, for each activation x of the network activations and each node weight w of the defined node weights: generating an activation sequence which is a unary representation of x/nₓ, a first weight sequence W_{L}, and a second weight sequence W_{R}, where the sequence W=(Wₙ_{_{w}}, Wₙ_{_{w}}₋₁, . . . , W₂, W₁, W₀) is a unary representation of w/n_{w}, the sequence V=(w₀, W₁, W₂, . . . , Wₙ_{_{w}}₋₁, Wₙ_{_{w}}) is the reverse of W, and nₓ is a multiple of n_{w} so that W_{L} and W_{R} are of length nₓ; and computing M_{S}(X, W_{L})+M_{S}(X, W_{R}) as an approximation for 2(x/nₓ)(w/n_{w}), wherein M_{S}(.,.) denotes stochastic multiplication, and providing a neural network output based on, at least in part, a set of computed approximations for 2(x/nₓ)(w/n_{w}) values.

### FIELD OF THE INVENTION

The disclosure relates generally to the generation and use of deterministic sequences for stochastic computing. The invention relates particularly to circuits and methods utilizing deterministic sequences in stochastic computing.

### BACKGROUND

Stochastic computing provides advantages such as low computation hardware area, fault tolerance, simple hardware implementation, and the possibility of trading off computation time and accuracy without changing hardware. In stochastic computing, a number is represented with a probability of a ‘1’ in a bit sequence, which is equal to the expected ratio of the number of ‘1’s to the total length of the bit sequence. For example, A=⅓ may be represented with a bit sequence of length n_{A}=12, where each bit is a ‘1’ with a probability of ⅓, so that the expected number of ‘1’s in the bit sequence is 4. The equivalent binary precision of A in this unary representation is p_{A}=log₂(n_{A})≈3.6. In a hardware implementation, a binary-to-stochastic conversion may be performed with a random number generator (RNG), and a stochastic-to-binary conversion may be performed with a counter (by counting the number of ‘1’s).

The stochastic representation is fault tolerant, as all the bits in the sequence have the same significance, and therefore the error induced by a bit flip has the same value as the equivalent binary precision. This contrasts with binary representations where flipping of higher significance bits can induce larger errors. More specifically, flipping of exponent bits in floating-point representations can induce very large errors. The stochastic representation also provides the opportunity to use very simple hardware for stochastic computation. For example, a multiplication operation can be performed by an AND gate, which is particularly appealing for computing convolutions and matrix multiplications in deep neural networks. Stochastic representations for computation also offer the possibility of trading off computation time and accuracy without changing hardware, i.e., a single pipeline can be used for computations with different precisions by changing the bit sequence lengths.

### SUMMARY

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later. In one or more embodiments described herein, devices, systems, computer-implemented methods, apparatuses and/or computer program products enable neural network inference computations using stochastic computing with deterministic sequences.

Aspects of the invention disclose methods, systems and computer readable media associated with providing neural network inference outputs by receiving a trained neural network having a set of defined node weights, determining a set of network activations according to network input data, for each activation x of the set of network activations and each node weight w of the set of defined node weights: generating a sequence X=(xₙ_{ₓ}, Xₙ_{ₓ}₋₁, . . . , X₂, X₁, X₀) which is a unary representation of x/nₓ, a first weight sequence W_{L}=(W, W, . . . , W) by repeating W for nₓ/n_{w} times, and a second weight sequence W_{R}=(V, V, . . . , V) by repeating V for nₓ/n_{w} times, where the sequence W=(Wₙ_{_{w}}, Wₙ_{_{w}}₋₁, . . . , W₂, W₁, W₀) is a unary representation of w/n_{w}, the sequence V=(W₀, W₁, W₂, . . . , Wₙ_{_{w}}₋₁, Wₙ_{_{w}}) is the reverse of W, and nₓ is a multiple of n_{w} so that W_{L} and W_{R} are of length nₓ; and computing M_{S}(X, W_{L})+M_{S}(X, W_{R}) as an approximation for 2(x/nₓ)(w/n_{w}), wherein M_{S}(.,.) denotes stochastic multiplication, and providing a neural network output based on, at least in part, a set of computed approximations for 2(x/nₓ)(w/n_{w}) values. Stochastic multiplication may include a logical AND operation on the input sequences, followed by counting the number of ‘1’s in the output sequences.

### BRIEF DESCRIPTION OF THE DRAWINGS

Through the more detailed description of some embodiments of the present disclosure in the accompanying drawings, the above and other objects, features and advantages of the present disclosure will become more apparent, wherein the same reference generally refers to the same components in the embodiments of the present disclosure.

FIG. 1 provides a schematic illustration of a computing environment, according to an embodiment of the invention.

FIG. 2 provides a flowchart depicting an operational sequence, according to an embodiment of the invention.

FIG. 3 provides a simplified schematic view of a circuit according to an embodiment of the invention.

### DETAILED DESCRIPTION

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein.

There are challenges that have limited the use of stochastic computing. The main challenge is the presence of random fluctuation errors associated with the use of random sequences. As sequence lengths increase, the numbers of ‘1’s approach their expected values for the operands and multiplication results. But increasing the sequence length has the drawback of increasing latency and power consumption. Another challenge is the area overhead associated with the use of RNGs typically implemented with linear feedback shift registers (LFSRs), which cannot be shared as the pseudorandom sequences need to be uncorrelated.

Disclosed embodiments enable the use of deterministic sequences as an alternative to pseudo-random sequences. In contrast to pseudo-random sequences, computation with appropriately chosen deterministic sequences provides guaranteed error bounds for given sequence lengths. Therefore, relatively shorter sequences can be used for computation provided that the errors are sufficiently low. It should be noted that if deterministic sequences are used instead of random or pseudorandom sequences, strictly speaking, the computation is no longer stochastic. This is because the (pseudo) randomness of the sequences is the only source of stochasticity in stochastic computing. However, since the basic concepts, techniques and approaches associated with stochastic computing remain applicable to deterministic sequences, it is customary to use the term stochastic computing irrespective of the type of sequences.

Throughout this disclosure, the terms stochastic computing and stochastic multiplication are used with respect to deterministic sequences, even though, strictly speaking, the described computations are not stochastic.

Disclosed embodiments provide a deterministic sequence and its application to convolutional neural networks. In the range of interest for neural network computation, the maximum error resulting from stochastic multiplications based on this deterministic sequence is lower than that resulting from the quantization of activations.

Aspects of the present invention relate generally to simplifying the hardware and/or software requirements for obtaining neural network inference outputs by utilizing stochastic multiplication to compute the inference output.

In accordance with aspects of the invention there is a method for determining and providing neural network inference outputs using stochastic multiplication to reduce hardware and software requirements. Disclosed methods include determining a set of activations from the trained model using input data, generating binary representations for the activations and weights, generating unary sequences of the binary representations, stochastically multiplying the activations and weights using the unary sequences, and combining the stochastic multiplication results yielding an inference output for the neural network.

Aspects of the invention provide an improvement in the technical field of approximate computing, particularly for neural network machine learning workloads. Disclosed methods simplify the software and hardware requirements necessary for convolution calculations and the matrix operations necessary for neural network inference outputs. Disclosed method achieves desired classification accuracy levels without requiring large chip areas for random number generation.

Aspects of the invention also provide an improvement to computer functionality. In particular, implementations of the invention are directed to a specific improvement to the way neural network inference calculations are completed, embodied in determining a set of activations from the trained model using input data, generating binary representations for the activations and weights, generating unary sequences of the binary representations, stochastically multiplying the activations and weights using the unary sequences, and combining the stochastic multiplication results yielding an inference output for the neural network.. As a result of utilizing stochastic computations for inference output calculations, hardware and software requirements are reduced yielding acceptable results in less time and with less energy consumption.

In an embodiment, one or more components of the system can employ hardware and/or software to solve problems that are highly technical in nature (e.g., determining a set of activations from the trained model using input data, generating binary representations for the activations and weights, generating unary sequences of the binary representations, stochastically multiplying the activations and weights using the unary sequences, combining the stochastic multiplication results yielding an inference output for the neural network, etc.). These solutions are not abstract and cannot be performed as a set of mental acts by a human due to the processing capabilities needed to facilitate neural network inference calculations, for example. Further, some of the processes performed may be performed by a specialized computer for carrying out defined tasks related to neural network matrix operations and convolutions. For example, a specialized computer can be employed to carry out tasks related to neural network computations, or the like.

In an embodiment, a computer implemented method provides neural network inference outputs. The method includes receiving a trained neural network having a set of defined node weights. In an embodiment, the neural network has been previously trained yielding a defined set of node weights for the network. The trained network includes the capacity to receive input data and generate network activations according to the training.

For each activation x of the set of network activations and each node weight w of the set of node weights represented in binary format as a starting point, the method provides an activation sequence X=(xₙ_{ₓ}, Xₙ_{ₓ}₋₁, . . . , X₂, X₁, X₀) which is a unary representation for x/nₓ; a first weight sequence W_{L}=(W, W, . . . , W) by repeating W for nₓ/n_{w} times, and a second weight sequence W_{R}=(V, V,., V) by repeating V for nₓ/n_{w} times, where the sequence W=(Wₙ_{_{w}}, Wₙ_{_{w}}₋₁, . . . , W₂, W₁, W₀) is a unary representation of w/n_{w}, the sequence V=(w₀, W₁, W₂, . . . , Wₙ_{_{w}}₋₁, Wₙ_{_{w}}) is the reverse of W, and nₓ is a multiple of n_{w} so that W_{L} and W_{R} are of length nₓ.

Using the unary sequences, disclosed systems and methods compute M_{S}(X, W_{L})+M_{S}(X, W_{R}) as an approximation for 2(x/nₓ)(w/n_{w}), wherein M_{S}(.,.) denotes stochastic multiplication; and subsequently provide a neural network inference output based on, at least in part, a set of computed approximations for 2(x/nₓ)(w/n_{w}) values. In an embodiment, the maximum multiplication error is +└(n_{w}+1)/4┘{2└(n_{w}+1)/4┘−n_{w}}/(2nₓn_{w}), where [.] denotes floor. This error is smaller than, or equal to +½nₓ (maximum quantization error for x) if n_{w}≤8, regardless of nₓ. This is beneficial because weights require lower precisions than activations in neural network computations.

As an example, let x=13, w=4, nₓ=18 and n_{w}=6. A unary representation of x/nₓ= 13/18 is given by the sequence X=(1, 1, 1, 1, 1, 1, 1, 1, 1, 1, 1, 1, 1, 0, 0, 0, 0, 0). A unary representation of w/n_{w}= 4/6 is given by the sequence W=(1, 1, 1, 1, 0, 0), and the reverse of W is given by V=(0, 0, 1, 1, 1, 1). Repeating W and V for nₓ/n_{w}=3 times yields W_{L}=(1, 1, 1, 1, 0, 0, 1, 1, 1, 1, 0, 0, 1, 1, 1, 1, 0,0) and W_{R}=(0,0,1,1,1,1,0,0,1,1,1,1,0,0,1,1,1,1), respectively. Performing a logical AND operation on X and W_{L} yields (1, 1, 1, 1, 0, 0, 1, 1, 1, 1, 0, 0, 1, 0, 0, 0, 0, 0), corresponding to M_{S}(X, W_{L})= 9/18, which is the ratio of the number of ‘1’s in this sequence to the length of this sequence. Similarly, performing a logical AND operation on X and W_{R} yields (0, 0, 1, 1, 1, 1, 0, 0, 1, 1, 1, 1, 0, 0, 0, 0, 0, 0), corresponding to M_{S}(X, W_{R})= 8/18. This computation approximates 2( 13/18)( 4/6) with 8/18+ 9/18.

In some embodiments, implementation of the disclosed methods may be facilitated using dedicated hardware including, for each binary weight w of bit width p_{w}, a p_{w}-bit up-counter (which may be shared with one or more weights, in some embodiments) and a p_{w}-bit comparator for generating a W_{L} sequence of length nₓ where p_{w}=[log₂(n_{w})], and [.] denotes ceiling, and a p_{w}-bit down-counter (which may be shared with one or more weights, in some embodiments) and a p_{w}-bit comparator for generating a W_{R} sequence of length nₓ, and for each binary activation x of bit width px, a px-bit up-counter or down-counter (which may be shared with one or more activations, in some embodiments) and a px-bit comparator for generating an X sequence of length nₓ where pₓ=[log₂(nₓ)]. The W_{L} and X sequences are inputs to a first AND gate to perform a first stochastic multiplication corresponding to M_{S}(X, W_{L}), and the W_{R} and X sequences are inputs to a second AND gate to perform a second stochastic multiplication corresponding to M_{S}(X, W_{R}).

The outputs of the two AND gates are inputs to a parallel counter which generates M_{S}(X, W_{L})+M_{S}(X, W_{R}) at its output after nₓ cycles by counting the total number of ‘1’s in the output sequences of the two AND gates, which is an approximate computation of 2(x/nₓ)(w/n_{w}) as described earlier. In some embodiments, the parallel counter may be shared among a set of weights wᵢ and activations xi, thus receiving the outputs of all the AND gates associated with these weights and activations, generating an approximation for the partial sum Σᵢ2(xᵢ/nₓ)(wᵢ/n_{w}). In an embodiment where weights have the same signs as their corresponding activations, the parallel counter is an up-counter. In another embodiment the parallel counter is a parallel up/down counter, and the outputs of the AND gates operating on weights and activations having the same signs as each other are connected to the ‘up’ input ports of the up/down parallel counter, and the outputs of the AND gates operating on weights and activations having opposite signs as each other are connected to the ‘down’ input ports of the parallel up/down counter.

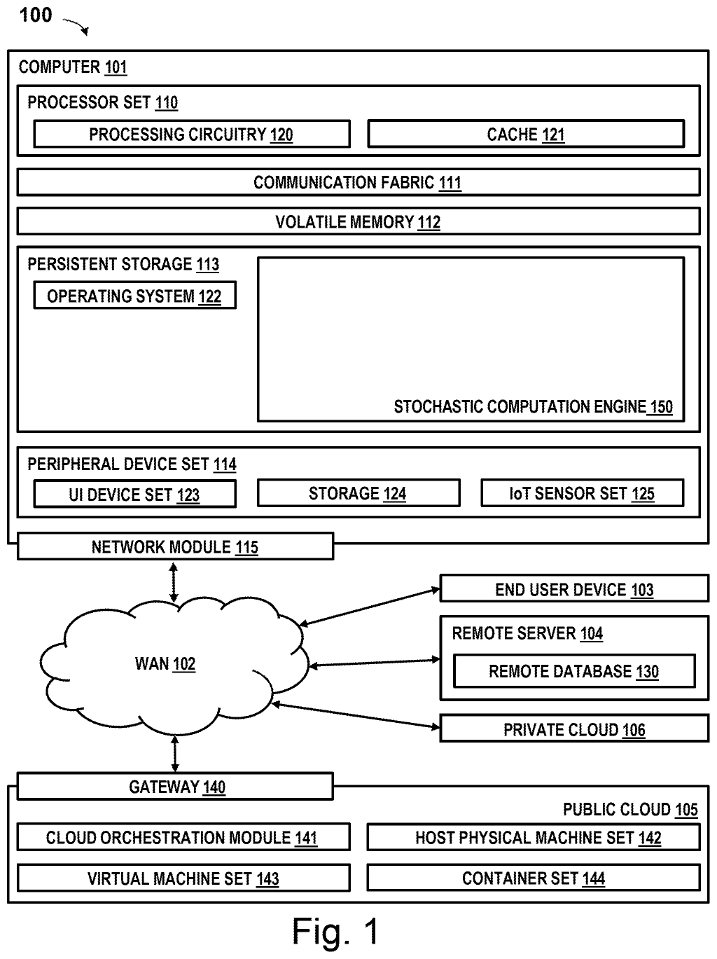

As shown in FIG. 1, computing environment 100 contains an example of an environment for the execution of at least some of the computer code involved in performing the inventive methods, such as providing neural network inference outputs, block 150. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 150, as identified above), peripheral device set 114 (including user interface (UI), device set 123, storage 124, and Internet of Things (IOT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods for providing neural network inference outputs may be stored in block 150 in persistent storage 113.

COMMUNICATION FABRIC 111 provides signal conduction paths that allow the various components of computer 101 to communicate with each other. Typically, this fabric includes switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 includes any type of volatile memory now known or to be developed in the future. Examples include dynamic type random access memory (RAM) or static type RAM. The volatile memory typically utilizes random access, but that is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

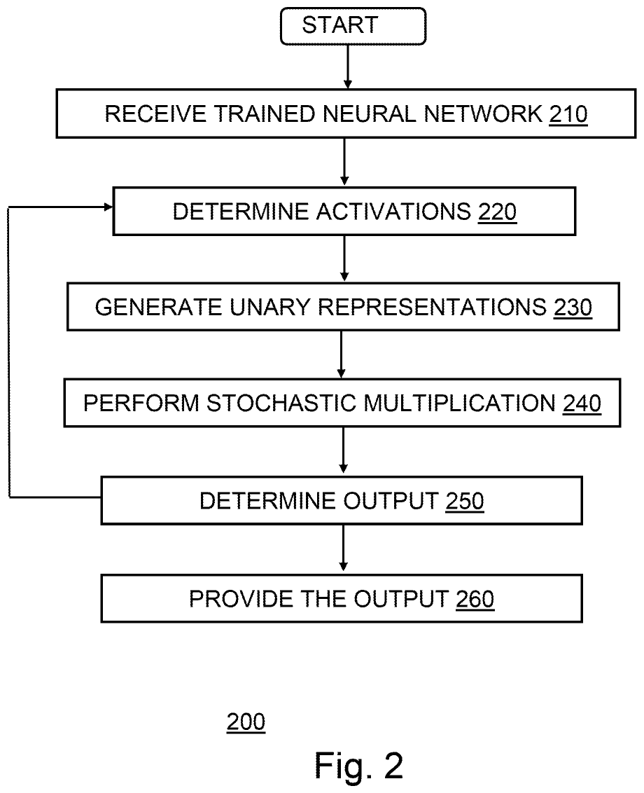

The disclosed systems and methods may be utilized to perform stochastic computations in any or all layers of a neural network. FIG. 2 provides a flowchart 200, illustrating exemplary activities associated with the practice of the disclosure. After program start, at block 210, systems and methods receive a trained neural network including a defined set of node weights. Such a previously trained neural network may also be referred to as a pretrained network. Well-known training techniques such as back-propagation could be used for pretraining a neural network, using platforms such as a general-purpose CPU or GPU, as known in the art. In addition, retraining (also known as fine-tuning) can be used to adjust (calibrate) the node weights of a pretrained network for a specific inference task, as known in the art. Typically, retraining is performed with forward propagation paths using the same (or similar) computations used in inference. For example, retraining may be performed using the disclosed stochastic multiplication operations in the forward propagation paths, while conventional floating-point multiplications are used in the backward propagation paths. Such retraining may be performed, for example, on the same platform used for pretraining, such as a general-purpose CPU or GPU. Whether or not retraining is performed, after the program start at block 210, a trained (pretrained or retrained) neural network with a defined set of node weights is received by the disclosed systems and methods for inference.

At block 220, the systems and methods determine a set of activations according to a processing of input data using the trained model. For the first (input) layer of a neural network, activations are determined directly according to an initial processing of input data using the trained model and known processing methods. For the subsequent layers of the neural network, activations are determined according to processing of output data from a previous layer(s) of the neural network, again using the trained model and known processing methods. These known processing methods may include but are not limited to shifting, scaling, and quantization. The quantization may include rounding and conversion from floating-point to fixed-point binary values.

At block 230, systems and methods generate sequences which are unary representations of each activation of the set of activations and each node weight of the set of node weights. In an embodiment, systems and methods are provided with binary values of predetermined bit widths (and therefore predetermined precisions) for each of the activations and node weights. These binary values may be obtained using known processing methods such as quantization, as described earlier. Systems and methods then convert the binary values to unary sequences. In this embodiment, systems and methods may utilize specialized circuits to convert the binary values to unary sequences. Such circuits include up-counter or down-counter elements (which may be shared across the set of activations) and individual comparator elements for converting each activation binary value to a unary sequence, as well as up-counters (which may be shared across the set of weights) together with individual comparators for converting the binary value of each weight to a first set of unary sequences. Such circuits further include down-counter elements (which may be shared across the set of weights) in addition to individual comparators for each weight to convert the binary value to a second set of unary sequences.

At block 240, systems and methods conduct stochastic multiplication using the activation and weight unary sequences as inputs. The stochastic multiplication may be performed using AND gates. More specifically, for each weight and activation, a first stochastic multiplication operation (e.g. logical AND) is performed on the generated unary sequence for the binary activation value and the first unary sequence generated for the binary weight value; and a second stochastic multiplication operation (e.g. logical AND) is performed on the same generated unary sequence for the binary activation value and the second unary sequence generated for the binary weight value. Stochastic-to-binary conversion is then performed by counting the number of ‘1’s in the output sequences of the AND gates, using a parallel counter with the output sequences of the AND gates as inputs to the parallel counter. The parallel counter may be shared among a set of weights wᵢ and activations xᵢ, thus generating an approximation for the partial sum Σᵢ2(xᵢ/nₓ)(w;/n_{w}).

At block 250 systems and methods combine the respective stochastic multiplication products using known processing methods including conversion from fixed-point binary to floating-point for further processing. For example, operations such as accumulation and scaling (including logical shifts, for example) may be used to process the partial sums and compute a full matrix multiplication or convolution, followed by applying an activation function such as a rectified linear unit (ReLU), or an output classifier function such as softmax. For the last (output) layer of a neural network, this yields the neural network inference output which systems and methods provide to a user in block 260. For other layers of the neural network, the processing result is provided to the subsequent layer of neural network in block 220 if stochastic computation is intended to be used in the subsequent layer. Otherwise, the subsequent layer is computed using conventional techniques. In some embodiments, convolutions and matrix multiplications in all layers of the neural network are computed using the disclosed systems and methods to take full advantage of the area and energy savings facilitated by the disclosed systems and methods.

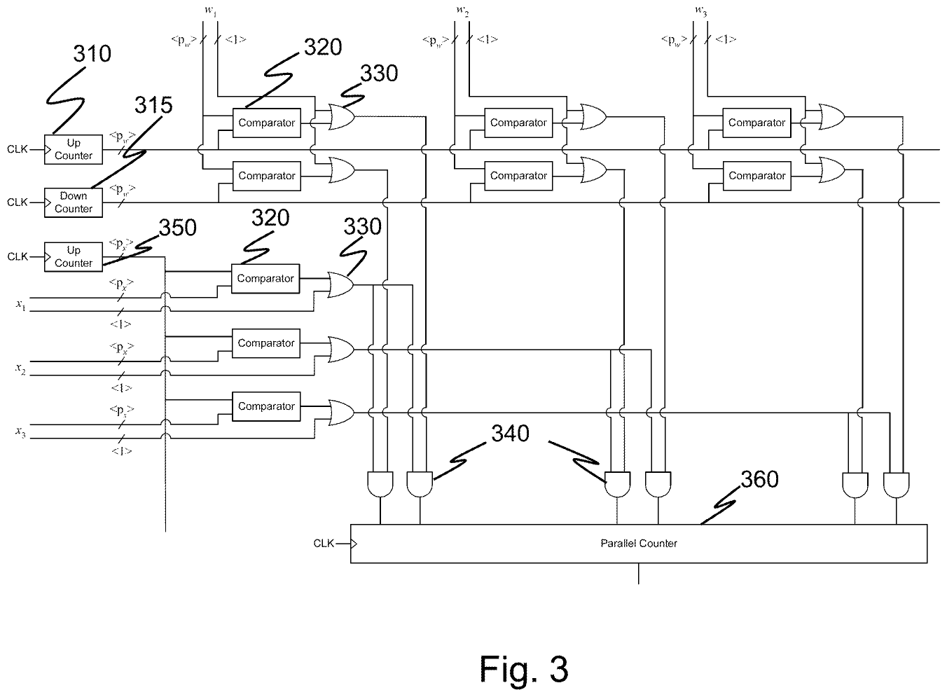

FIG. 3 provides a schematic illustration of a circuit of a hardware implementation of an embodiment of the invention. As shown in the Figure, for each binary weight w₁, w₂, and w₃ of bit width p_{w}, the circuit comprises a common p_{w}-bit up-counter 310 and an individual p_{w}-bit comparator 320 for generating a W_{L} sequence of length nₓ where p_{w}=[log₂(n_{w})], and [.] denotes ceiling, and a common p_{w}-bit down-counter 315 and an individual p_{w}-bit comparator 320 for generating a W_{R} sequence of length nₓ, and for each binary activation x₁, x₂, x₃ of bit width pₓ, a common pₓ-bit up-counter 350 and an individual pₓ-bit comparator 320 for generating an X sequence of length nₓ where pₓ=[log₂(nₓ)]. Each binary weight and activation is accompanied with an overflow bit which is an input to an OR gate 330 with its respective W_{L}, W_{R} or X sequence, forcing the sequence value to be ‘1’ when the overflow bit is ‘1’. These overflow bits are optional and may be omitted depending on the hardware implementation details. The W_{L} and X sequences (OR′ed with their respective overflow bits when present) are inputs to a first set of AND gates 340 to perform a first set of stochastic multiplications corresponding to M_{S}(X, W_{L}), and the W_{R} and X sequences (OR′ed with their respective overflow bits when present) are inputs to a second set of AND gates 340 to perform a second set of stochastic multiplications corresponding to M_{S}(X, W_{R}). The parallel counter 360 receives the outputs of the AND gates and generates an approximation for the partial sum Σᵢ₌₁³(xᵢ/nₓ)(wᵢ/n_{w}). This configuration facilitates parallel stochastic computations on multiple pairs of weights and activations in the form of single instruction, multiple data (SIMD). For illustration purposes, only three pairs of weights and activations are shown in FIG. 3.

It will be appreciated that FIG. 3 is a schematic illustration and does not include all the components required for computing the output of a layer in a neural network, including the components described with respect to FIG. 2, for processes such as conversion between floating-point and fixed-point binary, scaling, quantization, accumulation and activation functions. Such components and processing methods are widely used in neural network computations and are well-known to those familiar with the art. In addition, the circuit of FIG. 3 may operate in conjunction with control logic that receive decoded instructions from a processor, or it may include its own logic for fetching, decoding and/or executing instructions. These methods and approaches, and the required hardware components are well-known to those familiar with the art, and such details are omitted from FIG. 3 for simplicity. It will be also appreciated that the components shown in the circuit of FIG. 3 may be rearranged, and other variations and/or enhancements apparent to those familiar with the art may be contemplated. Particularly, various techniques and approaches commonly used in the design of hardware accelerators for neural networks computations including those utilizing stochastic computing may be employed as well. For example, zero-gating techniques may be used to skip unnecessary computations when sequence bits are ‘0’s, or longer sequences may be split into shorter ones and AND operations performed on them in parallel to reduce latency at the cost of increased hardware area, or the two stochastic multiplications M_{S}(X, W_{L}) and M_{S}(X, W_{R}) may be performed sequentially (i.e. using the same AND gate) for a weight and activation pair to reduce hardware area at the cost of increased latency. Moreover, the hardware block shown in FIG. 3 may be repeated multiple times to form a two-dimensional (2D) array, which may be used, for example, in conjunction with a systolic dataflow. Various mappings of neural networks to such a 2D array for computations such as matrix multiplication and convolution may be considered, and widely used dataflow approaches such as weight stationary, output stationery and combination thereof, may be utilized for a such a 2D array.

It is to be understood that although this disclosure includes a description on cloud computing, implementation of the teachings recited herein are not limited to a cloud computing environment. Rather, embodiments of the present invention are capable of being implemented in conjunction with any other type of computing environment now known or later developed.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions collectively stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A computer implemented method comprising:
receiving a trained neural network having a set of defined node weights;
determining a set of network activations according to network input data;
for each activation x of the set of network activations and each node weight w of the set of defined node weights:
generating an activation sequence X=(Xₙ_{ₓ}, Xₙ_{ₓ}₋₁, . . . , X₂, X₁, X₀) which is a unary representation of x/nₓ, a first weight sequence W_{L}=(W, W, . . . , W) by repeating W for nₓ/n_{w} times, and a second weight sequence W_{R}=(V, V, . . . , V) by repeating V for nₓ/n_{w} times, where the sequence W=(Wₙ_{_{w}}, Wₙ_{_{w}}₋₁, . . . , W₂, W₁, W₀) is a unary representation of w/n_{w}, the sequence V=(W₀, W₁, W₂, . . . , Wₙ_{_{w}}₋₁, Wₙ_{_{w}}) is the reverse of W, and nₓ is a multiple of n_{w} so that W_{L} and W_{R} are of length nₓ; and
computing M_{S}(X, W_{L})+M_{S}(X, W_{R}) as an approximation for 2(x/nₓ)(w/n_{w}),
wherein M_{S}(.,.) denotes stochastic multiplication; and
providing a neural network output based, at least in part, on a set of computed approximations for 2(x/nₓ)(w/n_{w}) values.

2. The computer implemented method according to claim 1, wherein the stochastic multiplication comprises a first logical AND operation on the activation sequence X and the first sequence W_{L}, and a second logical AND operation on the activation sequence X and the second weight sequence W_{R}, followed by counting the number of ‘1’s in the two sequences resulting from the said logical AND operations.

3. The computer implemented method according to claim 1, wherein an activation sequence X is generated using a circuit comprising an up-counter or down-counter circuit element and a comparator circuit element.

4. The computer implemented method according to claim 1, wherein a first weight sequence W_{L} is generated using a circuit comprising an up-counter circuit element and a comparator circuit element.

5. The computer implemented method according to claim 1, wherein a second weight sequence W_{R} is generated using a circuit comprising a down-counter circuit element and a comparator circuit element.

6. The computer implemented method according to claim 1, wherein the stochastic multiplication comprises a first logical AND operation on the activation sequence X and the first sequence W_{L} using a first AND gate circuit element, and a second logical AND operation on the activation sequence X and the second weight sequence W_{R} using a second AND gate circuit element, followed by counting the number of ‘1’s in the two sequences resulting from the said logical AND operations using a parallel counter circuit element.

7. The computer implemented method according to claim 1, wherein the neural network output provided by the method is an inference output of the neural network.

8. The computer implemented method according to claim 1, wherein the neural network output provided by the method is a forward propagation path output of the neural network during retraining to fine-tune the weights prior to inference.

9. A computer program product, the computer program product comprising one or more computer readable storage media and collectively stored program instructions on the one or more computer readable storage media, the stored program instructions which, when executed, cause one or more computer systems to:
receive a trained neural network having a set of defined node weights;
determine a set of network activations according to network input data;
for each activation x of the set of network activations and each node weight w of the set of defined node weights:
generate an activation sequence X=(Xₙ_{ₓ}, Xₙ_{ₓ}₋₁, . . . , X₂, X₁, X₀) which is a unary representation of x/nₓ, a first weight sequence W_{L}=(W, W, . . . , W) by repeating W for 1w/n_{w} times, and a second weight sequence W_{R}=(V, V, . . . , V) by repeating V for nₓ/n_{w} times, where the sequence W=(Wₙ_{_{w}}, Wₙ_{_{w}}₋₁, . . . , W₂, W₁, W₀) is a unary representation of w/n_{w}, the sequence V=(W₀, W₁, W₂, . . . , Wₙ_{_{w}}₋₁, Wₙ_{_{w}}) is the reverse of W, and nₓ is a multiple of n_{w} so that W_{L} and W_{R} are of length nₓ; and
compute M_{S}(X, W_{L})+M_{S}(X, W_{R}) as an approximation for 2(x/nₓ)(w/n_{w}),
wherein M_{S}(.,.) denotes stochastic multiplication; and
provide a neural network output based on, at least in part, a set of computed approximations for 2(x/nₓ)(w/n_{w}) values.

10. The computer program product according to claim 9, wherein the stochastic multiplication comprises a first logical AND operation on the activation sequence X and the first sequence W_{L}, and a second logical AND operation on the activation sequence X and the second weight sequence W_{R}, followed by counting the number of ‘1’s in the two sequences resulting from the said logical AND operations.

11. The computer program product according to claim 9, wherein the stored program instructions cause the one or more processors to generate an activation sequence X for an activation using a circuit comprising an up-counter or down-counter circuit element and a comparator circuit element.

12. The computer program product according to claim 9, wherein the stored program instructions cause the one or more processors to generate a first weight sequence W_{L} using a circuit comprising an up-counter circuit element and a comparator circuit element.

13. The computer program product according to claim 9, wherein the stored program instructions cause the one or more processors to generate a second weight sequence W_{R} using a circuit comprising a down-counter circuit element and a comparator circuit element.

14. The computer program product according to claim 9, wherein the stored program instructions cause the one or more processors to perform a first logical AND operation on the activation sequence X and the first sequence W_{L} using a first AND gate circuit element, and a second logical AND operation on the activation sequence X and the second weight sequence W_{R} using a second AND gate circuit element, and count the number of ‘1’s in the two sequences resulting from the said logical AND operations using a parallel counter circuit element.

15. A computer system for providing neural network inference outputs, the computer system comprising:
one or more computer processors;
one or more computer readable storage devices; and
stored program instructions on the one or more computer readable storage devices for execution by the one or more computer processors, the stored program instructions which, when executed, cause the one or more computer processors to:
receive a trained neural network having a set of defined node weights;
determine a set of network activations according to network input data;
for each activation x of the set of network activations and each node weight w of the set of defined node weights:
generate an activation sequence X=(xₙ_{ₓ}) Xₙ_{ₓ}₋₁, . . . , ×2, x₁, X₀) which is a unary representation of x/nₓ, a first weight sequence W_{L}=(W, W, . . . , W) by repeating W for 11w/n_{w} times, and a second weight sequence W_{R}=(V, V, . . . , V) by repeating V for nₓ/n_{w} times, where the sequence W=(Wₙ_{_{w}}, Wₙ_{_{w}}₋₁, . . . , W₂, W₁, W₀) is a unary representation of w/n_{w}, the sequence V=(w₀, W₁, W₂, . . . , Wₙ_{_{w}}₋₁, Wₙ_{_{w}}) is the reverse of W, and nₓ is a multiple of n_{w} so that W_{L} and W_{R} are of length nₓ; and
compute M_{S}(X, W_{L})+M_{S}(X, W_{R}) as an approximation for 2(x/nₓ)(w/n_{w}),
wherein M_{S}(.,.) denotes stochastic multiplication; and
provide a neural network output based on, at least in part, a set of computed approximations for 2(x/nₓ)(w/n_{w}) values.

16. The computer system according to claim 15, wherein the stochastic multiplication comprises a first logical AND operation on the activation sequence X and the first sequence W_{L}, and a second logical AND operation on the activation sequence X and the second weight sequence W_{R}, followed by counting the number of ‘1’s in the two sequences resulting from the said logical AND operations.

17. The computer system according to claim 15, wherein the stored program instructions causes the one or more processors to generate an activation sequence X using a circuit comprising an up-counter or down-counter circuit element and a comparator circuit element.

18. The computer system according to claim 15, wherein the stored program instructions cause the one or more processors to generate a first weight sequence W_{L} using a circuit comprising an up-counter circuit element and a comparator circuit element.

19. The computer system according to claim 15, wherein the stored program instructions cause the one or more processors to generate a second weight sequence W_{R} using a circuit comprising a down-counter circuit element and a comparator circuit element.

20. The computer system according to claim 15, wherein the stored program instructions cause the one or more processors to perform a first logical AND operation on the activation sequence X and the first sequence W_{L} using a first AND gate circuit element, and a second logical AND operation on the activation sequence X and the second weight sequence W_{R} using a second AND gate circuit element, and count the number of ‘1’s in the two sequences resulting from the said logical AND operations using a parallel counter circuit element.
